(19) United States
(12) Patent Application Publication
(10) Pub. No.: US 2021/0124807 A1
(43) Pub. Date: Apr. 29, 2021

(54) OPTIMAL OCCUPANCY DETECTION DEVICE PLACEMENT

(71) Applicant: International Business Machines Corporation, Armonk, NY (US)

(72) Inventors: Stefan Renard Maetschke, Ascot Vale (AU); Julian de Hoog, Greensborough (AU)

(21) Appl. No.: 16/665,026

(22) Filed: Oct. 28, 2019

(51) Int. Cl. G06F 17/50; G06F 9/451

(52) U.S. Cl. CPC G06F 17/509; G06F 9/451

(57) ABSTRACT

In an approach for optimal placement of occupancy detection devices, a processor engages a mobile platform to collect data within a building. A processor constructs a spatial map from the collected data. A processor constructs an occupancy map from the collected data. A processor creates a model from the spatial map and the occupancy map. A processor determines a set of occupancy detection devices and a placement for each occupancy detection device of the set of occupancy detection devices. A processor outputs the set of occupancy detection devices and the placement for each occupancy detection device of the set of occupancy detection devices.

### BACKGROUND

The present invention relates generally to the field of smart buildings, and more particularly to optimal occupancy detection device placement.

A smart building is any structure that uses automated processes to automatically control the building's operations including heating, ventilation, air conditioning, lighting, security, and other systems. A smart building uses sensors, actuators, and microchips in order to collect data and manage it according to a business' functions and services. This infrastructure helps owners, operators, and facility managers improve asset reliability and performance, which reduces energy use, optimizes how space is used, and minimizes the environmental impact of buildings.

Methods used to detect occupancy are often classified as “terminal” (physically connected to people or entities of interest) or “non-terminal” (placed in the environment), e.g., cameras, sensors, etc.

### SUMMARY

Aspects of an embodiment of the present invention disclose a method, computer program product, and computer system for optimal occupancy detection device placement. A processor engages a mobile platform to collect data within a building. A processor constructs a spatial map from the collected data. A processor constructs an occupancy map from the collected data. A processor creates a model from the spatial map and the occupancy map. A processor determines a set of occupancy detection devices and a placement for each occupancy detection device of the set of occupancy detection devices. A processor outputs the set of occupancy detection devices and the placement for each occupancy detection device of the set of occupancy detection devices.

### BRIEF DESCRIPTION OF THE DRAWINGS

FIG. 1 depicts a block diagram of a distributed data processing environment, in accordance with an embodiment of the present invention.

FIG. 2 depicts a flow chart of the steps of an occupancy detection program, in accordance with an embodiment of the present invention.

FIG. 3 depicts a block diagram of a computing device of distributed data processing environment, in accordance with an embodiment of the present invention.

### DETAILED DESCRIPTION

Embodiments of the present invention recognize that accurate occupancy detection is critical to the success of smart buildings. The location and number of persons across floors and rooms in a building needs to be accurately detected to optimize heating, lighting, air flow, and other building conditions. Non-terminal methods for occupancy detection, e.g., cameras, sensors, etc., benefit from the optimal placement of the devices to reduce costs through the number of devices needed and to increase reliability and accuracy of occupancy estimates. Buildings increasingly utilize Internet of Things (IoT) technology to measure and control environmental conditions. Thus, there is a need for a way to identify locations for optimal placement of occupancy detection devices to reduce costs for equipping buildings with IoT technology and to increase the quality of the environmental control by measuring room occupancy reliably and accurately at minimum cost.

Embodiments of the present invention propose a system and method for determining optimal locations for occupancy detection devices in a building. Embodiments of the present invention utilize a mobile platform, e.g., robot, drone, etc., equipped with a set of sensors for occupancy detection that traverses each floor of a building for a fixed period of time, constructs a three-dimensional (3D) spatial map of each floor, and counts the number of persons in each room or floor over time. Since the mobile platform is used for the initial set up of the occupancy detection devices, the mobile platform may employ more accurate and more costly sensors to ensure optimal locations are determined for less costly occupancy detection devices that will be more permanent in the building. Embodiments of the present invention can employ multiple types of sensors for sensing multiple types of quantities, e.g., infrared thermal, infrared for motion, ultrasonic, sonar, sonar pressure, vibration, etc. Embodiments of the present invention determine the optimal locations for occupancy detection devices in the building based on the collected data by the mobile platform.

Embodiment of the present invention recognize that the goal is to optimally place sensors to measure building occupancy reliably and accurately while limiting invasion of privacy, e.g., using cameras. Embodiment of the present invention may utilize cameras only during the data gathering phase. For the final placement of occupancy detection devices, embodiments of the present invention utilize less intrusive sensors, e.g., infrared sensors.

The present invention will now be described in detail with reference to the Figures.

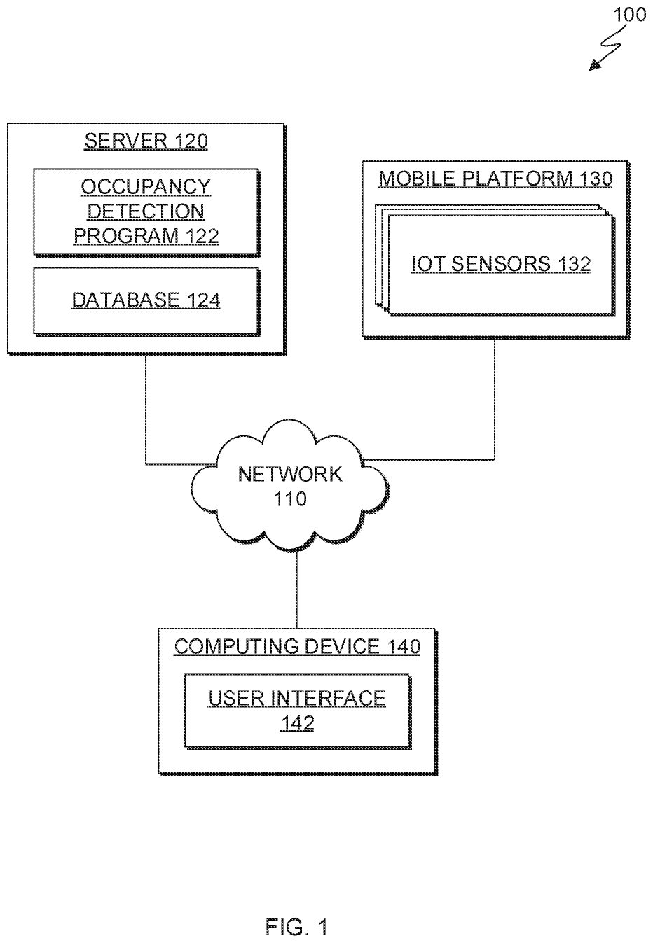

FIG. 1 depicts a functional block diagram illustrating distributed data processing environment 100, in accordance with an embodiment of the present invention. FIG. 1 provides only an illustration of one embodiment of the present invention and does not imply any limitations with regard to the environments in which different embodiments may be implemented. In the depicted embodiment, distributed data processing environment 100 includes server 120, mobile platform 130, and computing device 140 interconnected over network 110. Network 110 can be, for example, a local area network (LAN), a wide area network (WAN) such as the Internet, or a combination of the two, and can include wired, wireless, or fiber optic connections. In general, network 110 can be any combination of connections and protocols that will support communications between server 120, mobile platform 130, and computing device 140. Products manufacturing environment 100 may include additional servers, computers, or other devices not shown.

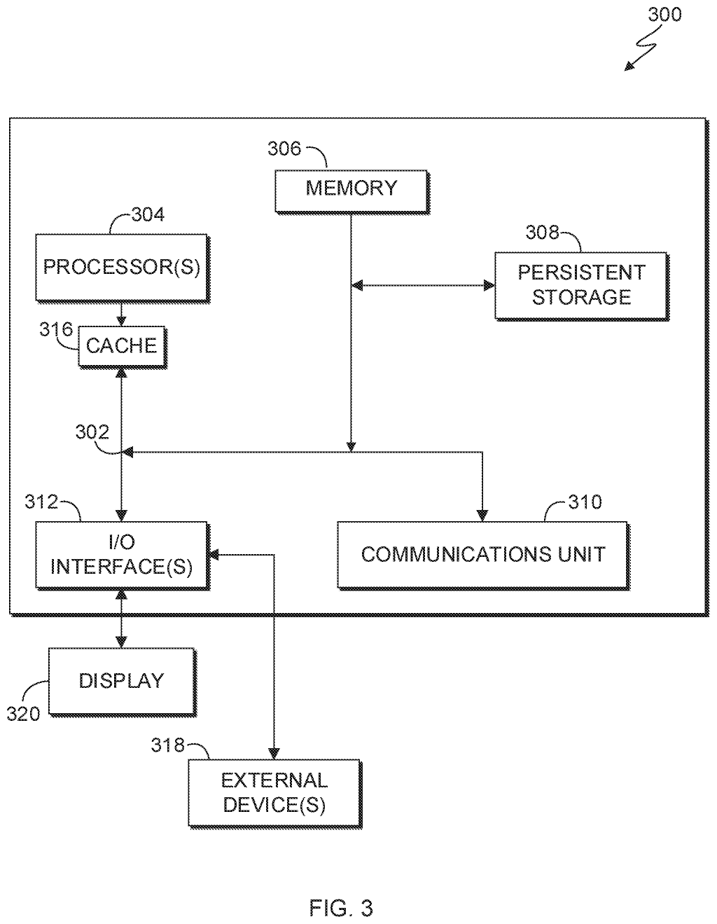

Server 120 operates to run occupancy detection program 122 and store and/or send data using database 124. In the depicted embodiment, server 120 houses occupancy detection program 122 and database 124. In other embodiments (not shown), occupancy detection program 122 and database 124 may be housed on separate computing devices. In some embodiments, server 120 may be a management server, a web server, or any other electronic device or computing system capable of receiving and sending data. In some embodiments, server 120 may be a laptop computer, tablet computer, netbook computer, personal computer (PC), a desktop computer, a smart phone, or any programmable electronic device capable of communicating with mobile platform 130 and computing device 140 via network 110. In other embodiments, server 120 represents a server computing system utilizing multiple computers as a server system, such as in a cloud computing environment. Server 120 may include components as described in further detail in FIG. 3.

Occupancy detection program 122 operates as a program for determining an optimal set of occupancy detection devices and optimal locations for the set of occupancy detection devices. In an embodiment, occupancy detection program 122 engages a mobile platform to collect data within a building. In an embodiment, occupancy detection program 122 constructs a spatial map from the collected data. In an embodiment, occupancy detection program 122 constructs an occupancy map from the collected data. In an embodiment, occupancy detection program 122 builds a model using the spatial map and the occupancy map. In an embodiment, occupancy detection program 122 determines an optimal set of occupancy detection devices and optimal locations for the set of occupancy detection devices based on the model. In an embodiment, occupancy detection program 122 outputs the optimal set of occupancy detection devices and optimal locations of the set of occupancy detection devices. In the depicted embodiment, occupancy detection program 122 resides on server 120. In other embodiments, occupancy detection program 122 may reside on another computing device (not shown), provided that occupancy detection program 122 has access to network 110.

Database 124 operates as a repository for data received, used, and/or output by occupancy detection program 122. Data received, used, and/or generated by storage optimization program 122 may include, but is not limited to, occupancy data and spatial mapping data. Database 124 can be implemented with any type of storage device capable of storing data and configuration files that can be accessed and utilized by server 120, such as a database server, a hard disk drive, or a flash memory. In an embodiment, database 124 is accessed by occupancy detection program 122 and/or server 120 to store and/or to access the data. In the depicted embodiment, database 124 resides on server 120. In another embodiment, database 124 may reside elsewhere within distributed data processing environment 100, provided that database 124 has access to network 110.

Mobile platform 130 operates as a mobile or moveable unit for collecting occupancy data and spatial mapping data through IoT sensors, i.e., IoT sensors 132. IoT sensors 132 can include, but are not limited to, cameras, microphones, laser range scanners, and infrared sensors. In an embodiment, mobile platform 130 traverses each floor of a building to collect the data. In an embodiment, mobile platform 130 sends the occupancy data and spatial mapping data collected to database 124 and/or occupancy detection program 122, for determining optimal permanent locations of occupancy detection devices.

Computing device 140 operates to run user interface 142. In some embodiments, computing device 140 may be, but is not limited to, an electronic device, such as a laptop computer, a tablet computer, a netbook computer, a personal computer (PC), a desktop computer, a smart phone, or any programmable electronic device capable of running user interface 142 and communicating (i.e., sending and receiving data) with server 120 and storage optimization program 122 via network 110. In some embodiments, computing device 140 represents one or more programmable electronic devices or combination of programmable electronic devices capable of executing machine readable program instructions and communicating with server 120 and/or other computing devices (not shown) within distributed data processing environment 100 via a network, such as network 110. In an embodiment, computing device 140 represents one or more devices associated with a user. In the depicted embodiment, computing device 140 includes an instance of user interface 142. Computing device 140 may include components as described in further detail in FIG. 3.

User interface 142 operates as a local user interface on computing device 140 through which a user can view the results, instruct occupancy detection program 122 to restart from step 210, and/or set up a schedule for when occupancy detection program 122 should run through another iteration of the process. For example, a user can instruct occupancy detection program 122 to restart another iteration because insufficient data was collected from the previous iteration. In another example, a user pre-sets occupancy detection program 122 to run once a month. In some embodiments, user interface 142 is a graphical user interface (GUI), a web user interface (WUI), and/or a voice user interface (VUI) that can display (i.e., visually) or present (i.e., audibly) information (such as graphics, text, and/or sound) sent from occupancy detection program 122 to a user via network 110. In an embodiment, user interface 142 is a local application interface of occupancy detection program 122. In an embodiment, user interface 142 enables a user to view the results, to instruct occupancy detection program 122 to restart from step 210, and/or to set up a schedule for when occupancy detection program 122 should run through another iteration of the process. In an embodiment, user interface 142 is capable of sending and receiving data (i.e., to and from occupancy detection program 122 via network 110, respectively).

In various embodiments of the present invention, a privacy component (not shown) is included that enables one or more users to opt-in or opt-out of being detected by mobile platform 130 in a certain location and that user information (e.g., personal, movement, and/or location information) shared with occupancy detection program 122. The privacy component enables the authorized and secure handling of user information, such as tracking information, as well as personal information that may have been obtained, is maintained, and/or is accessible. The user can be provided with notice of the collection of portions of the personal information and the opportunity to opt-in or opt-out of the collection process. Consent can take several forms. Opt-in consent can impose on the user to take an affirmative action before the data is collected. Alternatively, opt-out consent can impose on the user to take an affirmative action to prevent the collection of data before that data is collected. In some embodiments, the privacy component can be a part of user interface 142.

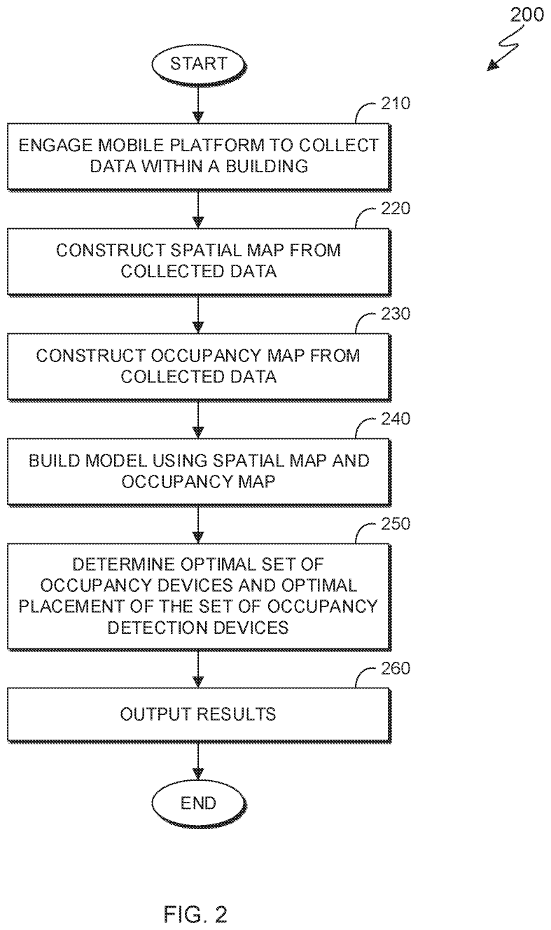

FIG. 2 depicts a flowchart 200 of the steps of occupancy detection program 122, in accordance with an embodiment of the present invention. In the depicted embodiment, occupancy detection program 122 engages a mobile platform to collect data within a building, constructs a spatial map from the collected data, constructs an occupancy map from the collected data, builds a model using the spatial map and the occupancy map, determines an optimal set of occupancy detection devices and optimal locations for the set of occupancy detection devices based on the model, and outputs the results. It should be appreciated that the process depicted in FIG. 2 illustrates one possible iteration of the process flow, which may repeat if instructed to by a user or based on a pre-set schedule set by a user.

In step 210, occupancy detection program 122 engages a mobile platform to collect data within a building. In an embodiment, occupancy detection program 122 instructs mobile platform 130 to collect data within a building. In an embodiment, occupancy detection program 122 instructs mobile platform 130 to collect occupancy data and spatial mapping data within a building by traversing each floor of the building. Occupancy data collected includes, but is not limited to, a number of persons within a defined space, which is defined by the spatial mapping data collected, at a certain time within the building. Spatial mapping data collected includes, but is not limited to, locations of rooms, walls, doors, power outlets, and other defined spaces within the building. In an embodiment, mobile platform 130 stores the collected data in database 124 and occupancy detection program 122 pulls the collected data from database 124 to use for the next step.

In step 220, occupancy detection program 122 constructs a spatial map from the collected data. In an embodiment, occupancy detection program 122 constructs a spatial map from the collected spatial mapping data. In an embodiment, occupancy detection program 122 constructs a 3D spatial map from the collected spatial mapping data that describes properties of defined spaces within the building.

In step 230, occupancy detection program 122 constructs an occupancy map from the collected data. In an embodiment, occupancy detection program 122 constructs an occupancy map from the collected occupancy data. In an embodiment, occupancy detection program 122 constructs a two-dimensional occupancy map from the collected occupancy data that describes occupancy over time within defined spaces within the building. For example, the occupancy map may show the occupancy in a meeting room during standard business hours and during non-business hours.

In step 240, occupancy detection program 122 builds a model using the spatial map and the occupancy map. In an embodiment, occupancy detection program 122 overlays the occupancy map and spatial map to build a model of occupancy within a defined space within the building.

In step 250, occupancy detection program 122 determines an optimal set of occupancy detection devices and optimal placement of the set of occupancy detection devices based on the model. In an embodiment, occupancy detection program 122 determines an optimal set of occupancy detection devices and optimal placement of the set of occupancy detection devices based on the model of occupancy within a defined space within the building. In an embodiment, occupancy detection program 122 selects an optimal set of occupancy detection devices from a library of occupancy detection devices with known technical specifications including a range and field of view. In an embodiment, occupancy detection program 122 selects the optimal set of occupancy detection devices based on the environmental limitations of the defined spaces within the building and the occupancy numbers as known by the model.

In several embodiment, occupancy detection program 122 determines an optimal set of occupancy detection devices and optimal placement of the set of occupancy detection devices by solving a multi-objective optimization problem. In an embodiment, to solve the multi-objective optimization problem, occupancy detection program 122 establishes an objective function, constraints, and decision variables.

In an embodiment, for the multi-objective optimization problem, occupancy detection program 122 establishes an objective function by defining the objectives of what is being optimized. In several embodiments, the objectives are to minimize a total costs of occupancy detection devices while achieving a given accuracy. In some embodiments, the objectives additionally consider a defined space priority, e.g., a storage room having a lower priority than a meeting room.

In an embodiment, for the multi-objective optimization problem, occupancy detection program 122 establishes constraints that are the rules required to be followed to be able to achieve a solution, e.g., the optimal set of occupancy detection devices and optimal placement of the set of occupancy detection devices. In several embodiments, the constraints account for defined space geometry (e.g., width, height, and depth of a meeting room), obstacles within a defined space (e.g., bookshelves, cabinets, desks, opened doors, room dividers, large plants, etc.), etc. In several embodiments, the main constraint is that areas frequented by persons are covered by at least one occupancy detection device. In some embodiments, the constraints account for suitability of occupancy detection device placement and availability of nearby power outlets for occupancy detection devices when needed.

In an embodiment, for the multi-objective optimization problem, occupancy detection program 122 establishes decision variables that are how the solution can be implemented. In several embodiments, the decision variables are the 3D placements of the occupancy detection devices including the occupancy detection device's tilt, orientation, and/or target angle, i.e., a direction of the occupancy detection device's field of vision.

In step 260, occupancy detection program 122 outputs the optimal set of occupancy detection devices and optimal placement of the set of occupancy detection devices. In an embodiment, occupancy detection program 122 outputs the results of the determination to a user through a user interface on a computing device, e.g., user interface 142 on computing device 140. In an embodiment, occupancy detection program 122 enables a user through a user interface on a computing device to view the results, to instruct occupancy detection program 122 to restart from step 210, and/or to set up a schedule for when occupancy detection program 122 should run through another iteration of the process. For example, a user instructs occupancy detection program 122 to restart another iteration because insufficient data was collected from the previous iteration. In another example, a user pre-sets occupancy detection program 122 to run once a month. In an embodiment, occupancy detection program 122 enables a user through a user interface on a computing device to send user feedback about the accuracy of the spatial map, the occupancy map, the model, and/or the optimal set of occupancy detection devices and optimal placement of the set of occupancy detection devices.

FIG. 3 depicts a block diagram of computer 300 suitable for server 120, mobile platform 130, and/or computing device 140, in accordance with an illustrative embodiment of the present invention. It should be appreciated that FIG. 3 provides only an illustration of one implementation and does not imply any limitations with regard to the environments in which different embodiments may be implemented. Many modifications to the depicted environment may be made.

Computer 300 includes communications fabric 302, which provides communications between cache 316, memory 306, persistent storage 308, communications unit 310, and input/output (I/O) interface(s) 312. Communications fabric 302 can be implemented with any architecture designed for passing data and/or control information between processors (such as microprocessors, communications and network processors, etc.), system memory, peripheral devices, and any other hardware components within a system. For example, communications fabric 302 can be implemented with one or more buses or a crossbar switch.

Memory 306 and persistent storage 308 are computer readable storage media. In this embodiment, memory 306 includes random access memory (RAM). In general, memory 306 can include any suitable volatile or non-volatile computer readable storage media. Cache 316 is a fast memory that enhances the performance of computer processor(s) 304 by holding recently accessed data, and data near accessed data, from memory 306.

Occupancy detection program 122 may be stored in persistent storage 308 and in memory 306 for execution and/or access by one or more of the respective computer processors 304 via cache 316. In an embodiment, persistent storage 308 includes a magnetic hard disk drive. Alternatively, or in addition to a magnetic hard disk drive, persistent storage 308 can include a solid state hard drive, a semiconductor storage device, read-only memory (ROM), erasable programmable read-only memory (EPROM), flash memory, or any other computer readable storage media that is capable of storing program instructions or digital information.

The media used by persistent storage 308 may also be removable. For example, a removable hard drive may be used for persistent storage 308. Other examples include optical and magnetic disks, thumb drives, and smart cards that are inserted into a drive for transfer onto another computer readable storage medium that is also part of persistent storage 308.

Communications unit 310, in these examples, provides for communications with other data processing systems or devices. In these examples, communications unit 310 includes one or more network interface cards. Communications unit 310 may provide communications through the use of either or both physical and wireless communications links. Programs, such as occupancy detection program 122, may be downloaded to persistent storage 308 through communications unit 310.

I/O interface(s) 312 allows for input and output of data with other devices that may be connected to server 120, mobile platform 130, and/or computing device 140. For example, I/O interface 312 may provide a connection to external devices 318 such as a keyboard, keypad, a touch screen, and/or some other suitable input device. External devices 318 can also include portable computer readable storage media such as, for example, thumb drives, portable optical or magnetic disks, and memory cards. Software and data used to practice embodiments of the present invention can be stored on such portable computer readable storage media and can be loaded onto persistent storage 308 via I/O interface(s) 312. I/O interface(s) 312 also connect to a display 320.

Display 320 provides a mechanism to display data to a user and may be, for example, a computer monitor.

Programs described herein is identified based upon the application for which it is implemented in a specific embodiment of the invention. However, it should be appreciated that any particular program nomenclature herein is used merely for convenience, and thus the invention should not be limited to use solely in any specific application identified and/or implied by such nomenclature.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A computer-implemented method for optimal placement of occupancy detection devices, the computer-implemented method comprising:
engaging, by one or more processors, a mobile platform to collect data within a building;
constructing, by one or more processors, a spatial map from the collected data;
constructing, by one or more processors, an occupancy map from the collected data;
creating, by one or more processors, a model from the spatial map and the occupancy map;
determining, by one or more processors, a set of occupancy detection devices and a placement for each occupancy detection device of the set of occupancy detection devices; and
outputting, by one or more processors, the set of occupancy detection devices and the placement for each occupancy detection device of the set of occupancy detection devices.

2. The computer-implemented method of claim 1, wherein the spatial map is three-dimensional.

3. The computer-implemented method of claim 1, wherein the mobile platform is a robot.

4. The computer-implemented method of claim 1, wherein the collected data comprises spatial mapping data and occupancy data.

5. The computer-implemented method of claim 1, wherein creating the model from the spatial map and the occupancy map comprises:
overlaying, by one or more processors, the occupancy map on the spatial map.

6. The computer-implemented method of claim 1, wherein determining the set of occupancy detection devices and the placement for each occupancy detection device of the set of occupancy detection devices is based on solving a multi-objective optimization problem, wherein the multi-objective optimization problem comprises an objective function, a set of constraints, and a set of decision variables.

7. The computer-implemented method of claim 6, wherein the objective function defines the objects that are to minimize a total costs of occupancy detection devices while achieving a given accuracy.

8. A computer program product for optimal placement of occupancy detection devices, the computer program product comprising:
one or more computer readable storage media and program instructions stored on the one or more computer readable storage media, the program instructions comprising:
program instructions to engage a mobile platform to collect data within a building;
program instructions to construct a spatial map from the collected data;
program instructions to construct an occupancy map from the collected data;
program instructions to create a model from the spatial map and the occupancy map;
program instructions to determine a set of occupancy detection devices and a placement for each occupancy detection device of the set of occupancy detection devices; and
program instructions to output the set of occupancy detection devices and the placement for each occupancy detection device of the set of occupancy detection devices.

9. The computer program product of claim 8, wherein the spatial map is three-dimensional.

10. The computer program product of claim 8, wherein the mobile platform is a robot.

11. The computer program product of claim 8, wherein the collected data comprises spatial mapping data and occupancy data.

12. The computer program product of claim 8, wherein the program instructions to create the model from the spatial map and the occupancy map comprise:
program instructions to overlay the occupancy map on the spatial map.

13. The computer program product of claim 8, wherein the program instructions to determine the set of occupancy detection devices and the placement for each occupancy detection device of the set of occupancy detection devices is based on solving a multi-objective optimization problem, wherein the multi-objective optimization problem comprises an objective function, a set of constraints, and a set of decision variables.

14. The computer program product of claim 13, wherein the objective function defines the objects that are to minimize a total costs of occupancy detection devices while achieving a given accuracy.

15. A computer system for optimal placement of occupancy detection devices, the computer system comprising:
one or more computer processors;
one or more computer readable storage media;
program instructions stored on the computer readable storage media for execution by at least one of the one or more processors, the program instructions comprising:
program instructions to program instructions to engage a mobile platform to collect data within a building;
program instructions to construct a spatial map from the collected data;
program instructions to construct an occupancy map from the collected data;
program instructions to create a model from the spatial map and the occupancy map;
program instructions to determine a set of occupancy detection devices and a placement for each occupancy detection device of the set of occupancy detection devices; and
program instructions to output the set of occupancy detection devices and the placement for each occupancy detection device of the set of occupancy detection devices.

16. The computer system of claim 15, wherein the spatial map is three-dimensional.

17. The computer system of claim 15, wherein the collected data comprises spatial mapping data and occupancy data.

18. The computer system of claim 15, wherein the program instructions to create the model from the spatial map and the occupancy map comprise:
program instructions to overlay the occupancy map on the spatial map.

19. The computer system of claim 15, wherein the program instructions to determine the set of occupancy detection devices and the placement for each occupancy detection device of the set of occupancy detection devices is based on solving a multi-objective optimization problem, wherein the multi-objective optimization problem comprises an objective function, a set of constraints, and a set of decision variables.

20. The computer system of claim 19, wherein the objective function defines the objects that are to minimize a total costs of occupancy detection devices while achieving a given accuracy.
